(19) United States
(12) Patent Application Publication
(10) Pub. No.: US 2013/0176151 A1
(43) Pub. Date: Jul. 11, 2013

(54) SERIALIZER

(71) Applicant: Electronics and Telecommunications Research, Daejeon (KR)

(72) Inventors: Byung Hun MIN, Daejeon (KR); Mun Yang Park, Daejeon (KR); Hyun Kyu Yu, Daejeon (KR)

(73) Assignee: Electronics and Telecommunications Research Institute, Daejeon (KR)

(21) Appl. No.: 13/660,284

(22) Filed: Oct. 25, 2012

(30) Foreign Application Priority Data
Jan. 11, 2012 (KR) 10-2012-0003442

(51) Int. Cl. H03M 9/00

(52) U.S. Cl. 341/101

(57) ABSTRACT

A serializer includes a clock generator configured to receive N reference clock signals (φ_<N−1:0>) (where N is a natural number) having different phases, and generate first clock signals (φ_<N−1:0>) and second clock signals (φd_<N−1:0>); a logic circuit configured to generate output signals (φo_<N−1:0>) of N parallel data pieces using the first clock signals and the second clock signals; and a drive circuit configured to serialize data corresponding to N output signals received from the logic circuit, and output the serialized data.

### CROSS-REFERENCE TO RELATED APPLICATIONS

The present application claims priority to Korean patent application number 10-2012-0003442, filed on Jan. 11, 2012, which is incorporated by reference in its entirety.

### BACKGROUND OF THE INVENTION

The present invention relates to a serializer, and more particularly to a serializer for preventing glitch and jitters from occurring in an output signal when operating at a high-speed low voltage.

FIG. 1A is a timing diagram illustrating a 5-phase clock and output of a serializer that uses a 5-phase as a clock. FIG. 1B is a circuit diagram illustrating a data serializer with multiple phases according to the related art.

In FIG. 1A, φ<4:0> is a reference clock signal of a data serializer having a duty ratio of 50%, rising times of individual reference clock signals (φ<0>˜φ<4>) are sequentially arranged at equal intervals.

That is, if φ<0> has a rising time at a time t0, φ<1> has a rising time at a time t1, φ<0> has a rising time at a time t2, φ<3> has a rising time at a time t3, and φ<4> has a rising time at a time t4.

The output signal of a data serializer using multiple phase clocks is characterized in that it can serialize as many data units as the number of multiple phases within one period of a clock signal. As can be seen from FIG. 1A, a serializer that uses 5 phases as a clock is designed to serialize 5 data units (i.e., D0 to D4) corresponding to the number of 5 phases during one period of an input clock, and outputs the 5 serialized data units at at an output node (SER_OUT).

FIG. 1B is a circuit diagram illustrating a conventional data serializer with multiple phases. For reference, it is assumed that the data serializer of FIG. 1B has 5 phases.

Referring to FIG. 1B, the conventional serializer inserts a load resistor (RLOAD) between a power-supply voltage (VDD) and an output node (SER_OUT), and is configured to include as many branches as the number of multiple phases between the output node (SER_OUT) and a ground terminal. Since it is assumed that the serializer of FIG. 1B uses 5 phases (i.e., 5-phase signal), each branch includes an AND gate, an NMOS, and a resistor.

However, the serializer according to the conventional art has the following problems during a high-speed operation.

First, a glitch may occur between clocks of multiple phases or may also occur due to a difference in position between a clock and data. That is, a phase difference generated when phase alignment is achieved between clocks or between data and clock may encounter the glitch problem.

Second, jitters may occur due to unbalance between a rising time and a falling time. Two transistors of one branch have relatively high ON-resistance. If the ON-resistance of two transistors is higher than load resistance (RLOAD), there occurs a relatively high difference between the rising time and the falling time, resulting in the occurrence of jitters in the serializer.

Therefore, a serializer for preventing glitch and jitters from occurring in an output signal obtained at a high-speed low voltage, and a data serialization method thereof are needed.

The related art of the present invention has been disclosed in Korean Patent Laid-open Publication No. 10-2005-0013810 (published on Feb. 5, 2005).

### SUMMARY OF THE INVENTION

Various embodiments of the present invention are directed to providing a serializer that substantially obviates one or more problems due to limitations or disadvantages of the related art. Embodiments of the present invention provide a serializer and a method for serializing parallel data, which can prevent glitch and jitters from occurring in an output signal obtained at a high-speed low voltage.

In accordance with an embodiment, a serializer includes a clock generator configured to receive N reference clock signals (φ_<N−1:0>) (where N is a natural number) having different phases, and generate first clock signals (φ_<N−1:0>) and second clock signals (φo_<N−1:0>) of N logic circuit configured to generate output signals (φo_<N−1:0>) of N parallel data pieces using the first clock signals and the second clock signals; and a drive circuit configured to serialize data corresponding to N output signals received from the logic circuit, and output the serialized data.

The K-th clock signal of the first clock signals (where K is a natural number) may have two rising edge times, wherein a first rising edge time and a second rising edge time are located at times t(K) and t(K+1), respectively. The K-th clock signal of the second clock signals may have one rising edge time, wherein the rising edge occurs at a time of generating a first falling edge of a K-th clock signal of the first clock signals, and a falling edge of the K-th clock signal of the second clock signals occurs at a time of generating a second falling edge of the K-th clock signal of the first clock signals.

The clock generator may be configured as a combination of several AND gates and several NAND gates so as to generate the first clock signals and the second clock signals, and a combination of two NAND gates receiving different signals respectively may be used to generate each of the first clock signals, and one AND gate receiving different signals respectively may be used to generate each of the second clock signals.

The logic circuit may include a NOR gate and a D flip-flop which are used to process each of the N parallel data pieces and thus output an output signal corresponding to the processed data.

The drive circuit may include a load resistor between a power-supply voltage and an output terminal, and N branches including NMOS transistors configured to receive N signals from the logic circuit are located between the output terminal and a ground terminal of the drive circuit unit, such that the drive circuit data serializes and outputs data corresponding to the output signal entered through each of the branch.

As described above, the serializer according to the present invention can prevent the occurrence of glitch caused by a phase difference under phase alignment between data and a clock or between one clock and another clock. In more detail, differently from the conventional method, a D flip-flop is mounted to a logic circuit of the serializer according to the embodiment of the present invention, such that the inventive serializer can perform data serialization using the rising edge time of a clock signal, resulting in no glitch problems.

In addition, impedance from an output node to a ground terminal according to the present invention is lower than that of the conventional structure, such that the serializer according to the present invention is beneficial to a high-speed operation. In addition, the load resistance (RLOAD) is tuned in response to an operation frequency, such that the serializer according to the present invention can be applied to a broadband serializer.

### BRIEF DESCRIPTION OF THE DRAWINGS

FIG. 1A is a timing diagram illustrating a 5-phase clock and output of a serializer that uses a 5-phase as a clock.

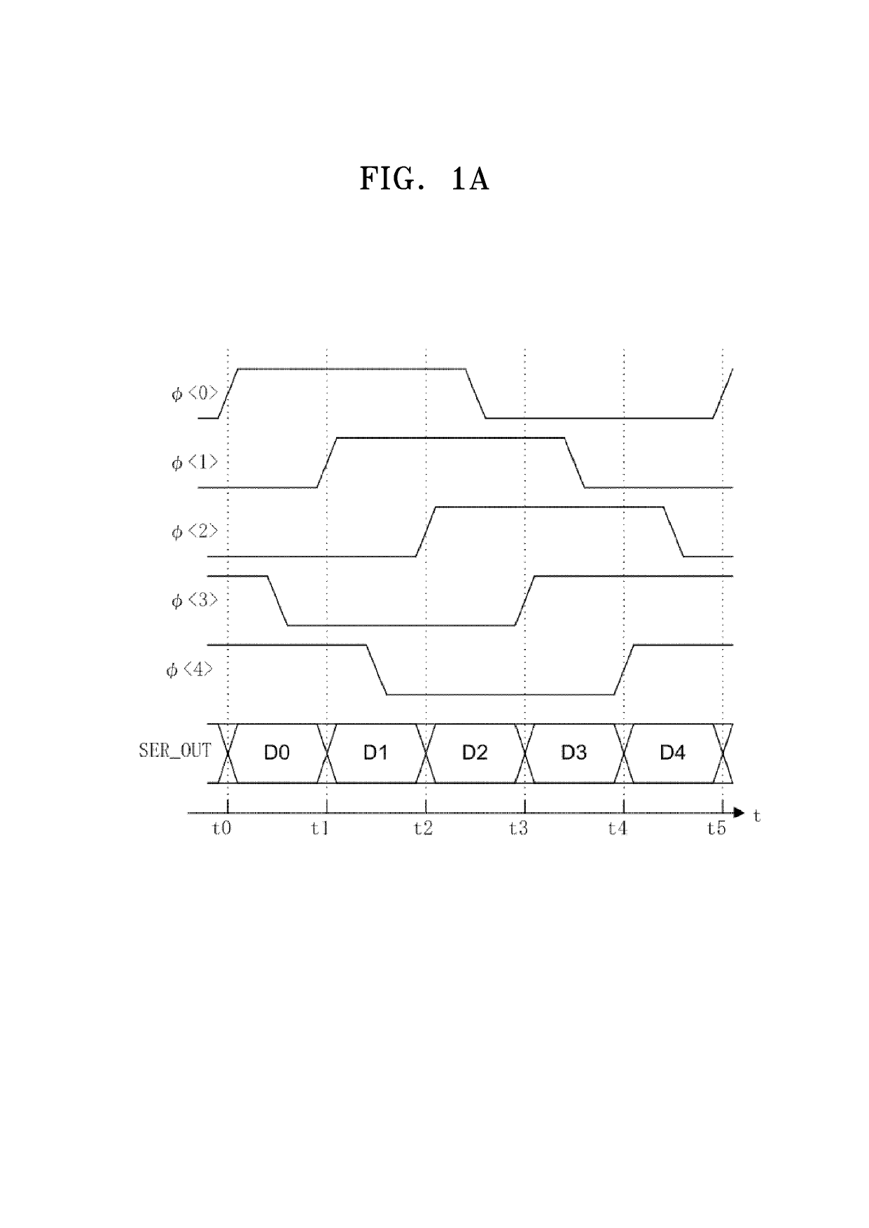

FIG. 1B is a circuit diagram illustrating a data serializer with multiple phases according to the related art.

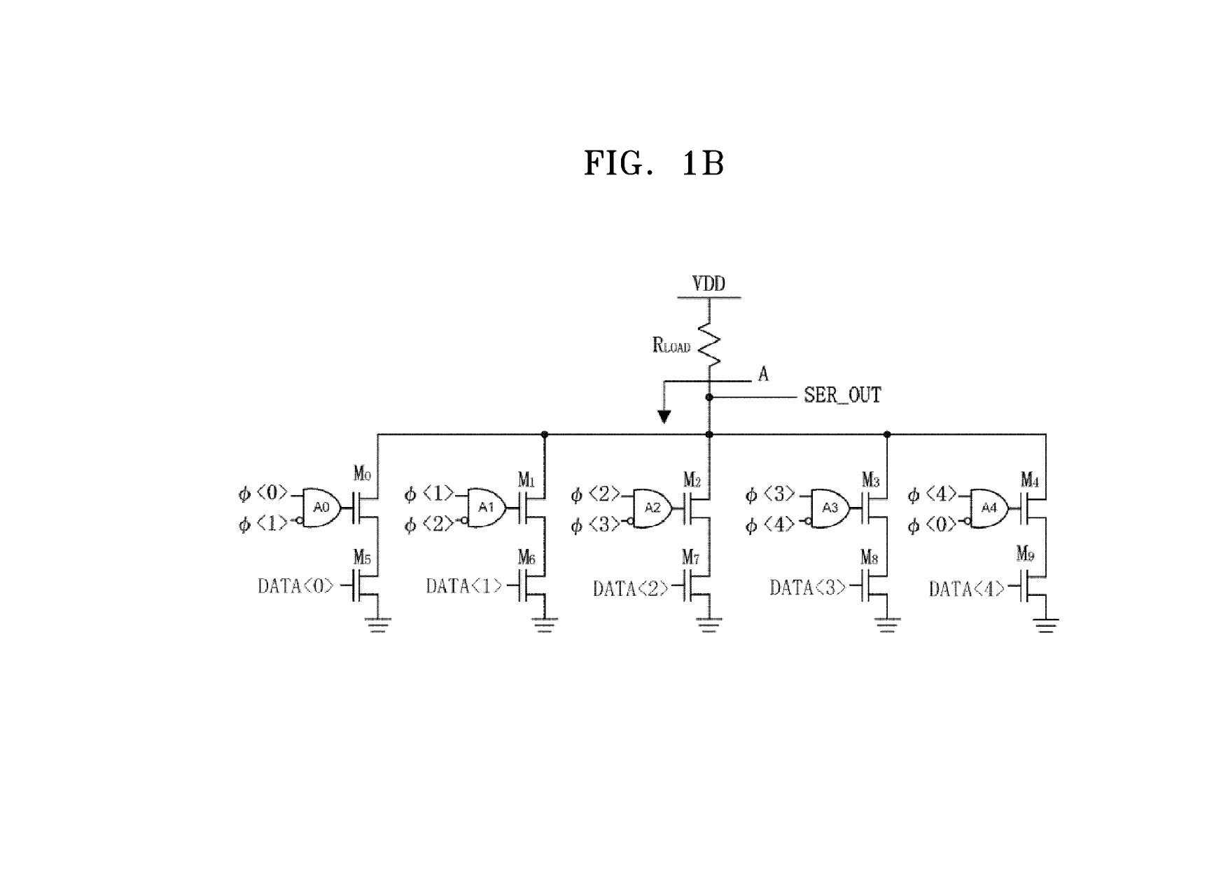

FIG. 2A is a block diagram illustrating a serializer according to an embodiment of the present invention.

FIG. 2B is a timing diagram illustrating a logic circuit unit of a serializer according to an embodiment of the present invention.

FIG. 2C is a circuit diagram illustrating a logic circuit unit of the serializer according to an embodiment of the present invention.

FIG. 3A is a circuit diagram illustrating a clock generation circuit of a serializer including 5 phases according to an embodiment of the present invention.

FIG. 3B is a timing diagram illustrating a clock generation circuit of a serializer including 5 phases according to an embodiment of the present invention.

FIG. 4A is a circuit diagram illustrating a logic circuit unit of a serializer including 5 phases according to an embodiment of the present invention.

FIG. 4B is a circuit diagram illustrating a drive circuit unit of a serializer including 5 phases according to an embodiment of the present invention.

FIG. 4C is a timing diagram illustrating a serializer including 5 phases according to an embodiment of the present invention.

### DESCRIPTION OF SPECIFIC EMBODIMENTS

Reference will now be made in detail to the embodiments of the present invention, examples of which are illustrated in the accompanying drawings. Wherever possible, the same reference numbers will be used throughout the drawings to refer to the same or like parts. A serializer according to the present invention will hereinafter be described in detail with reference to the accompanying drawings. In the drawings, line thicknesses or sizes of elements may be exaggerated for clarity and convenience. Also, the following terms are defined considering function of the present invention, and may be differently defined according to intention of an operator or custom. Therefore, the terms should be defined based on overall contents of the specification.

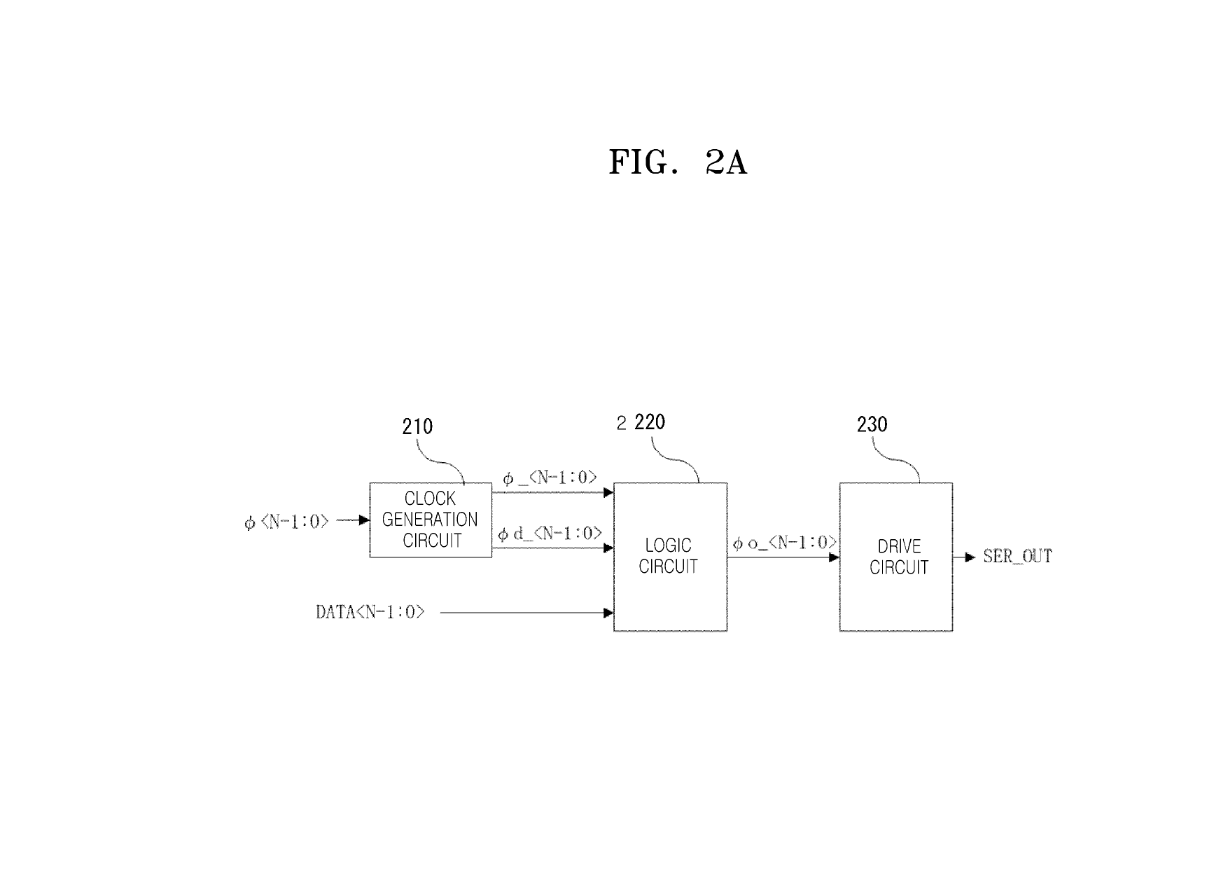

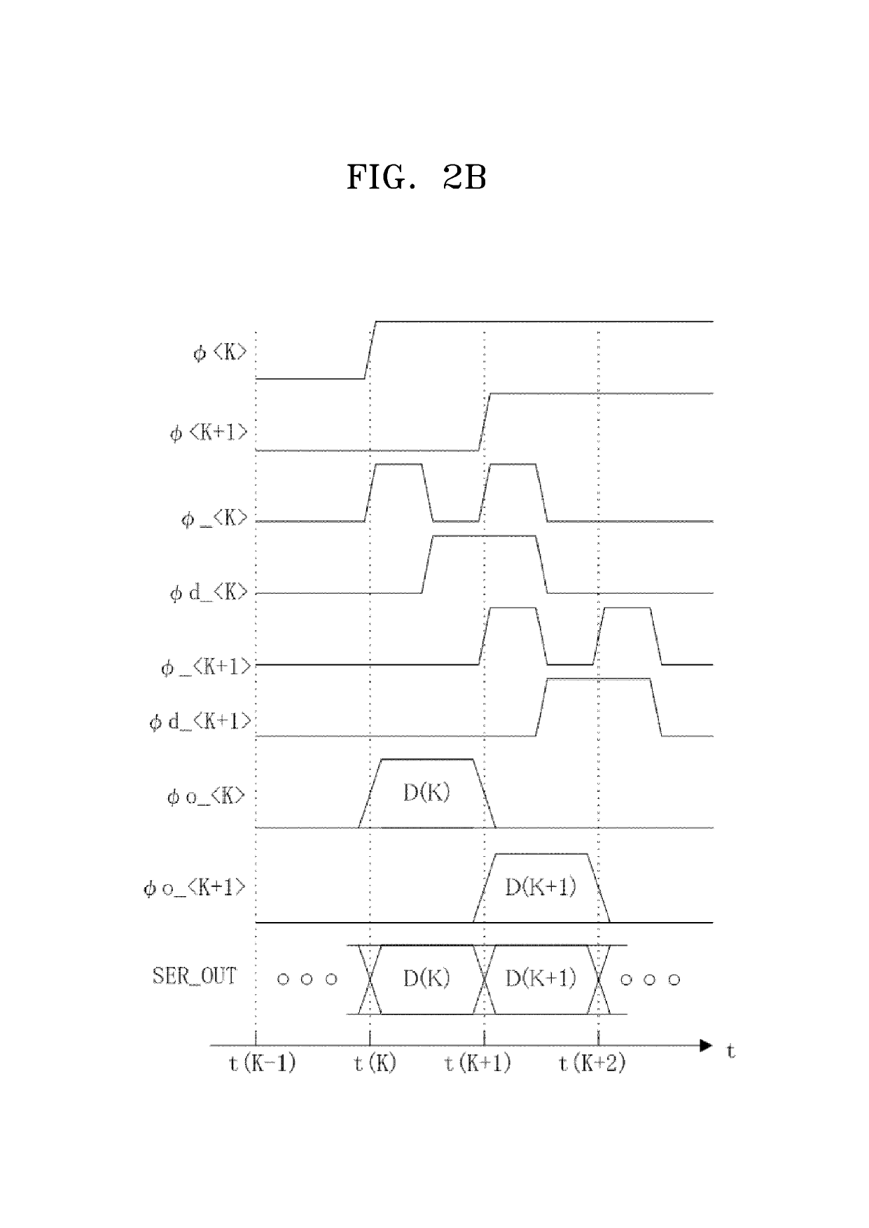

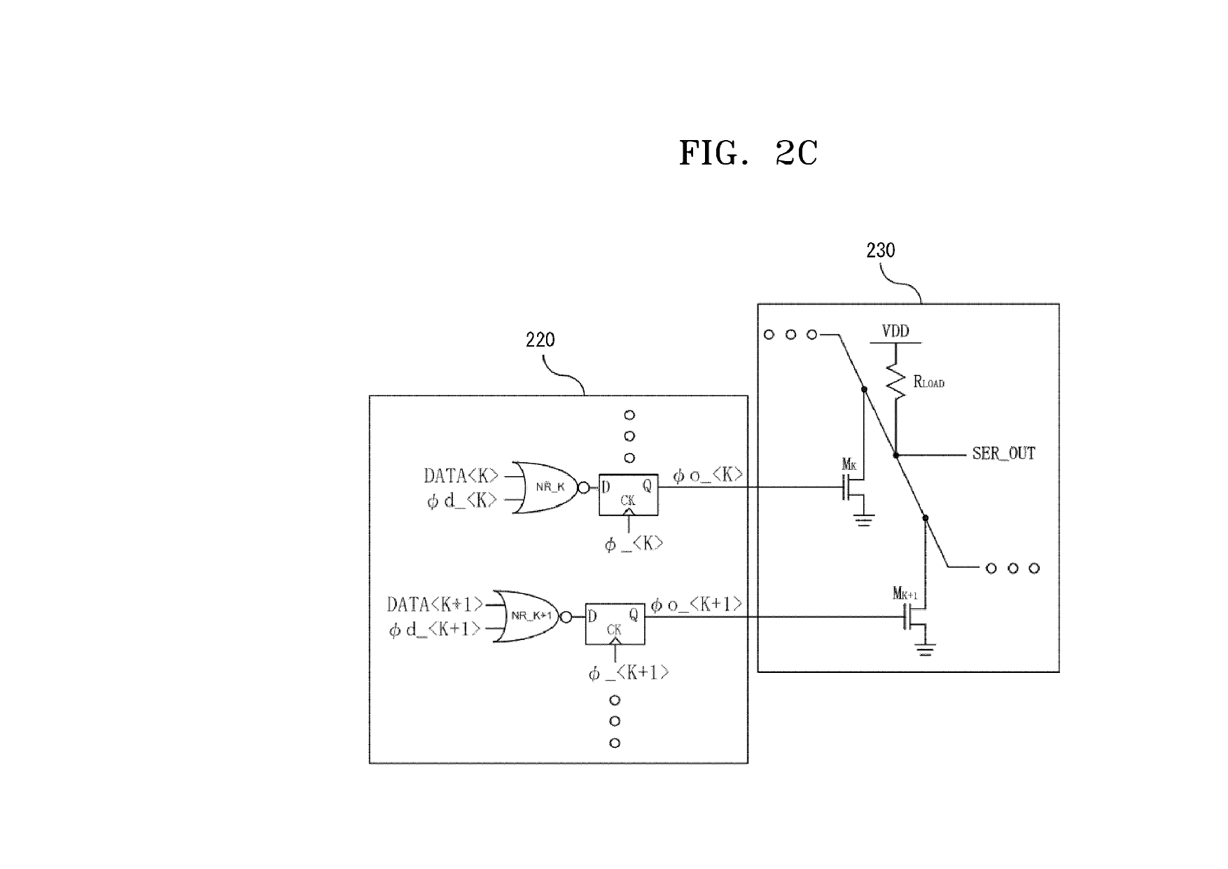

FIG. 2A is a block diagram illustrating a serializer according to an embodiment of the present invention. FIG. 2B is a timing diagram illustrating a logic circuit unit of a serializer according to an embodiment of the present invention. FIG. 2C is a circuit diagram illustrating a logic circuit unit of the serializer according to an embodiment of the present invention.

Referring to FIG. 2A, the serializer includes a clock generation circuit 210, a logic circuit unit 220, and a drive circuit unit 230.

The clock generation circuit 210 receives N reference clock signals φ<N−1:0> (where N is a natural number) having different phases, such that it generates two conversion clock signals (i.e., a first clock signal (φ_<N−1:0>) and a second clock signal (φd_<N−1:0>)).

The K-th and (K+1)-th waveforms (where K is a natural number) of the first clock signal (φ_<N−1:0>) and the second clock signal (φd_N−1:0>) that are output from the clock generation circuit 210 having received N reference clock signals (φ<N−1:0>) are shown in FIG. 2B.

Referring to FIG. 2B, a K-th clock signal (φ_<K>) of a first clock signal (φ_<N−1:0>) generated from the clock generation circuit 210 has two rising edge times that are respectively located at two times t(K) and t(K+1).

In contrast, the K-th clock signal (φd_<K>) of the second clock signal (φd_<N−1:0>) generated from the clock generation circuit 210 has only one rising edge time. The rising edge time is identical to a first falling edge time of the K-th clock signal (φ_<K>) of the first clock signal. In addition, the falling edge time of the K-th clock signal (φd_<K>) of the second clock signal is identical to a second falling edge time of the K-th clock signal (φ_<K>) of the first clock signal.

The (K+1)-th clock (φ_<K+1>) of the first clock signal (φ_<N−1:0>) generated from the clock generation circuit 210 also has two rising edge times that are respectively located at t(K+1) and t(K+2). In addition, the (K+1)-th clock signal (φd_K+1>) of the second clock signal (φd_<N−1:0>) generated from the clock generation circuit 210 has only one rising edge time, and is identical to a first falling edge time of the (K+1)-th clock signal (φ_<K+1>) of the first clock signal. In addition, the falling edge time of the (K+1)-th clock signal (φd_<K+1>) of the second clock signal is identical to a second falling edge time of the (K+1)-th clock signal (φ_<K+1>) of the first clock signal.

Referring to FIG. 2A, the logic circuit unit 220 of the serializer receives the first clock signal and the second clock signal from the clock generation circuit 210. In addition, the logic circuit unit 220 further receives N parallel data pieces (DATA<N−1:0>), such that it generates and outputs an output signal (φo_<N−1:0>).

The drive circuit unit 230 receives the output signal (φo_<N−1:0>) of the logic circuit unit 220 as an input, and outputs the received signal (φo_<N−1:0>) to an output signal (SER_OUT) of the serializer.

FIG. 2C shows detailed circuit diagrams of the logic circuit unit 220 and the drive circuit unit 230.

As described above, conversion clock signals generated by the clock generation circuit 210 are input to the logic circuit unit 220 shown in FIG. 2C, such that N parallel data pieces (DATA<N−1:0>) are sequentially arranged at the rising edge time of the clock signal (φ<N−1:0>) including N multiple phases.

The logic circuit unit 220 for sequentially arranging N data pieces will hereinafter be described with reference to the attached drawings.

Referring to FIG. 2C, the logic circuit unit 220 includes one NOR gate and one D flip-flop that are connected in series for each data processing.

For example, when processing the K-th data (DATA<K>) from among N parallel data pieces, the K-th data and the second clock signal (φd_<K>) are applied to a NOR gate (NR_K), and the output signal of the NOR gate is connected to an input terminal D of the D flip-flop. In this case, the first clock signal (φ_<K>) is input to a clock terminal CK of the D flip-flop.

The output terminal Q of the D flip-flop is connected to a gate terminal (M_{K}) of the NMOS transistor of the drive circuit unit 230, such that the output signal (φo_<K>) is input to the corresponding gate terminal.

When constructing the logic circuit unit 220 as shown in FIG. 2C, a data value D(K) of the output signal (φo_<K>) corresponding to the K-th data (DATA<K>) is output at a time between t(K) and t(K+1).

The (K+1)-th data (DATA<K+1>) from among N parallel data pieces can be processed in the same manner as in the above-mentioned K-th data processing, and as such a detailed description thereof will be omitted herein for convenience of description. Although FIGS. 2B and 2C exemplarily show the K-th data processing and the (K+1)-th data processing, it should be noted that (N−2) remaining data processing steps are identical to the K-th or (K+1)-th data processing.

If the above-mentioned process is performed for N data pieces (DATA<N−1:0>), the sequential output signals (φo_<N−1:0>) of the logic circuit unit 220 are respectively input to the drive circuit unit 230, and the drive circuit unit 230 generates/outputs an output waveform (SER_OUT) of the serializer.

Referring to FIG. 2C, the load resistance (RLOAD) is connected between the power-supply voltage VDD and the output terminal (SER_OUT) of the drive circuit unit 230, and NMOS transistors are connected between the output terminal (SER_OUT) and a ground terminal.

The output signals (for example, φo_<K>, φo_<K+1>, etc. shown in FIG. 2C) of the logic circuit unit 220, i.e., the output signals of individual D flip-flops, are respectively applied to gate terminals (i.e., M_{K}, M_{K+1}, or the like) of the corresponding NMOS transistors from among N NMOS transistors contained in the drive circuit unit 230.

Each output signal of the logic circuit unit 220 through each NMOS transistor is input in units of a time unit (i.e., t(K−1), t(K), t(K+1) or the like), and the data values D(K) of the individual output signals (φo_<N−1:0>) are serialized through the output terminal (SER_OUT) as shown in FIG. 2B, such that the serialized output signals are sequentially output.

In more detail, when the logic circuit unit 220 outputs N parallel data pieces (i.e., data values D<0>˜D<N−1>) corresponding to the output signals (φo_<0>˜φo_<N−1>), the output parallel data pieces are sequentially provided through N branches contained in the drive circuit unit 230, i.e., are sequentially provided through branches configured to include one NMOS transistor (i.e., M₀˜M_{N-}1) located between the output terminal (SER_OUT) and the ground terminal. As shown in FIG. 2B, the provided data values are serialized in the order of D(0), D(1), . . . , D(K), D(K+1), . . . , D(N−1) through the output node (SER_OUT) of the serializer.

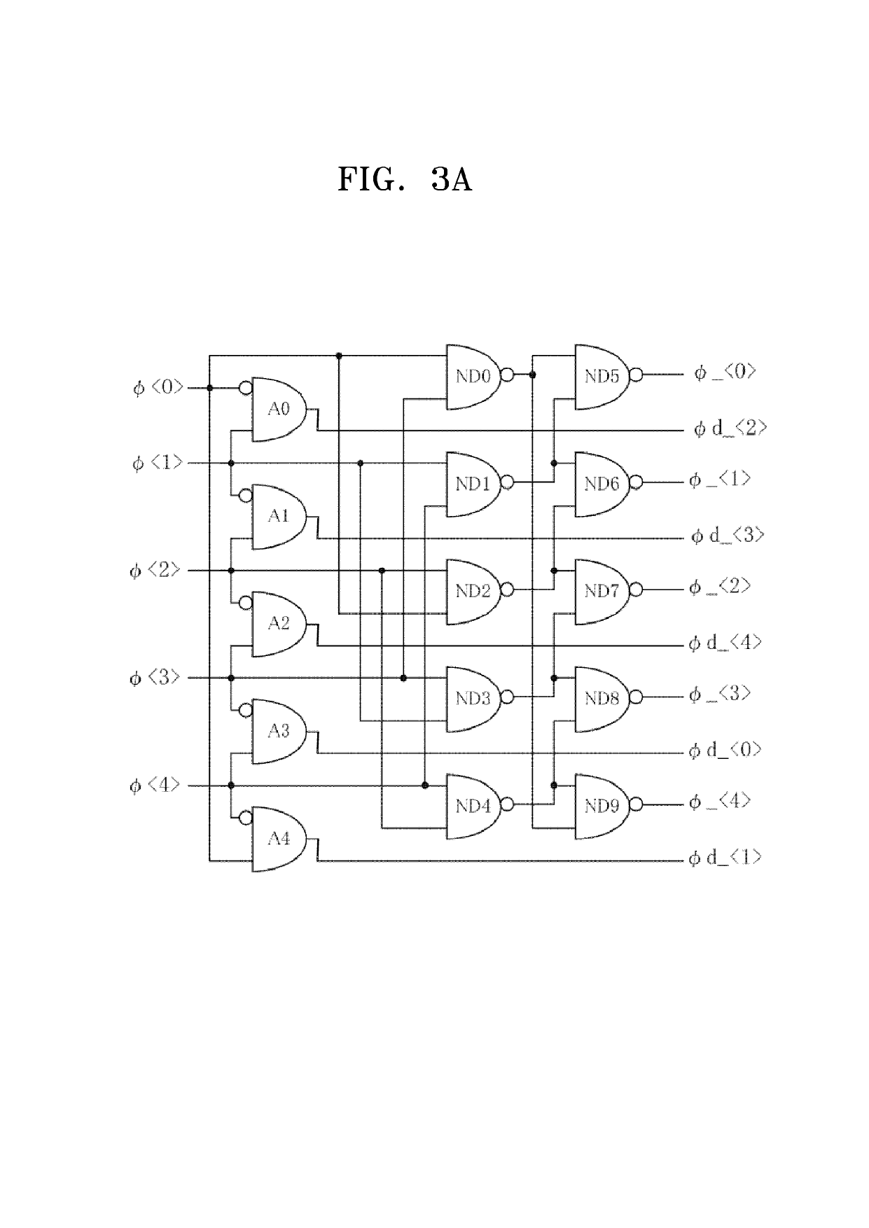

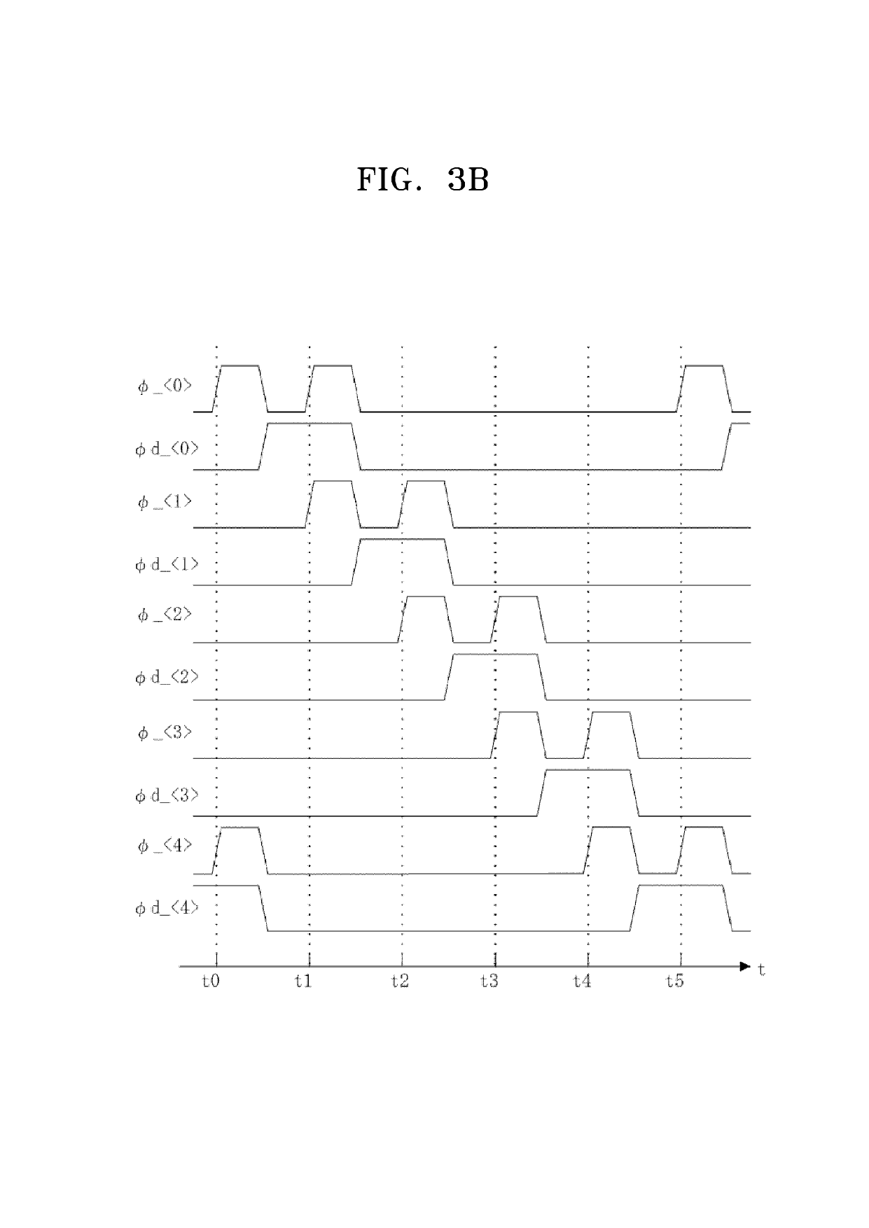

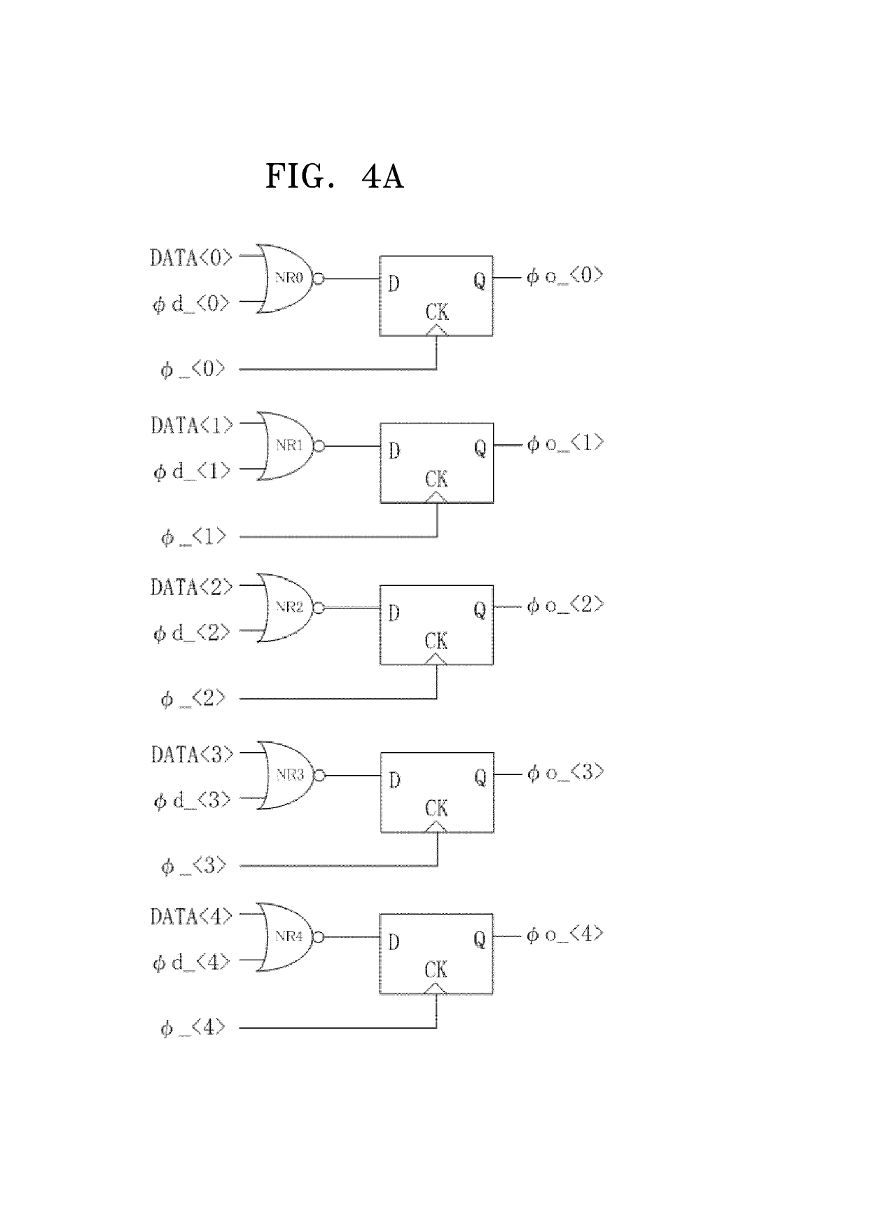

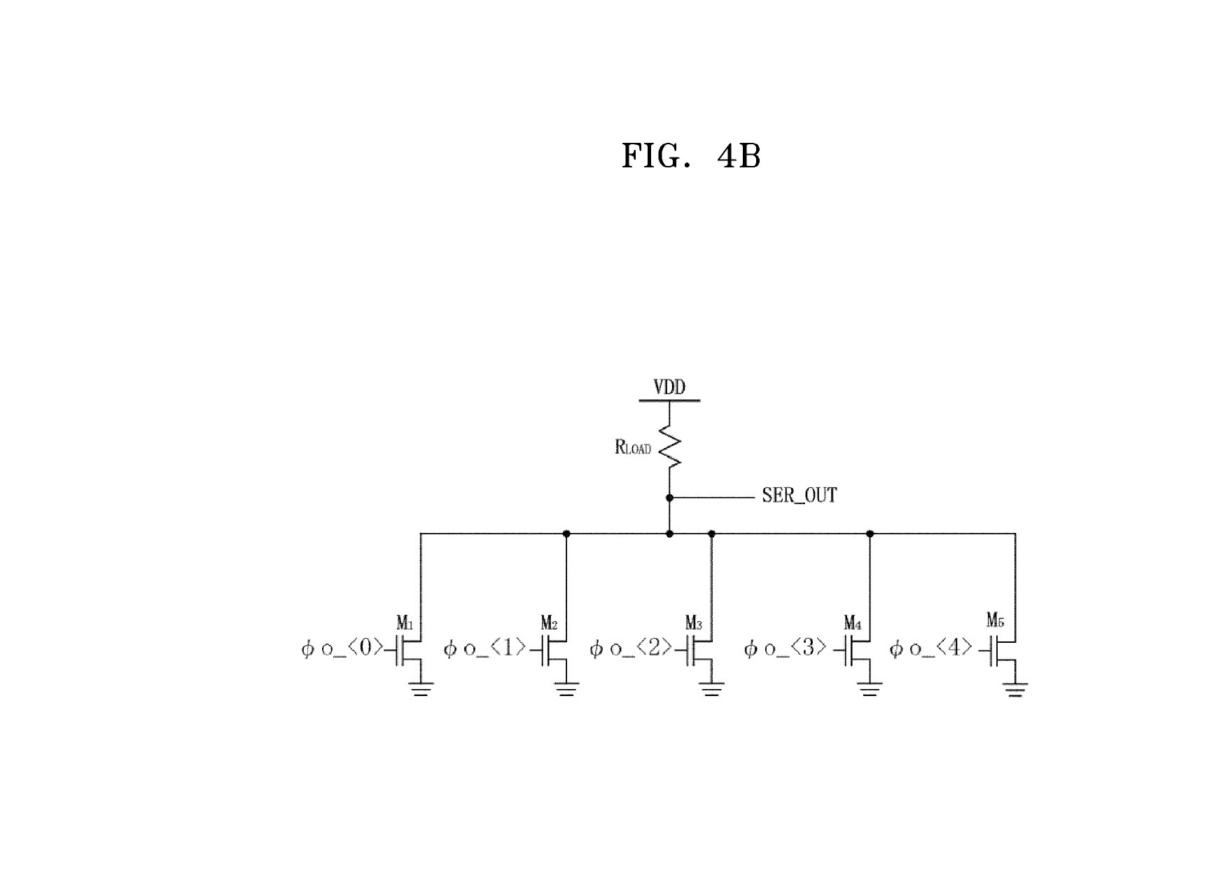

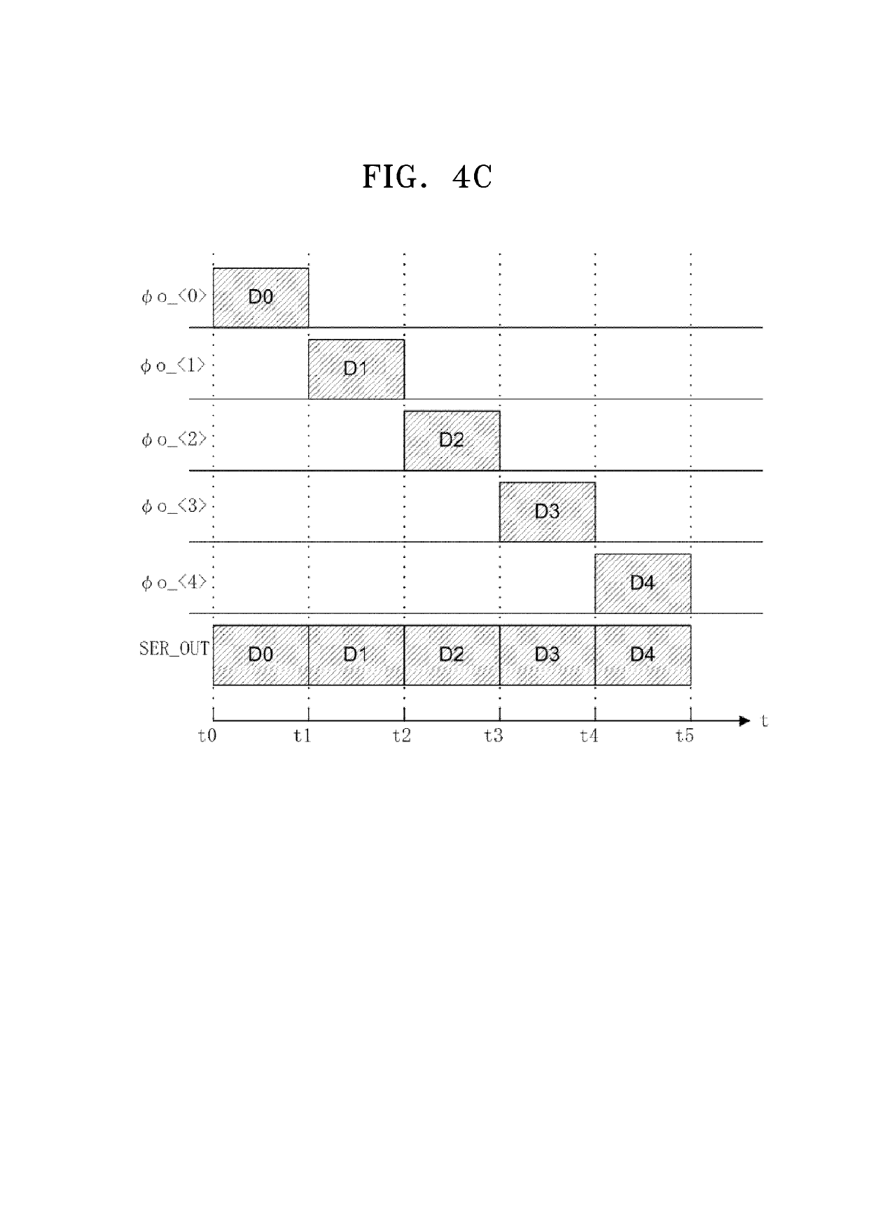

FIG. 3A is a circuit diagram illustrating a clock generation circuit of a serializer including 5 phases according to an embodiment of the present invention. FIG. 3B is a timing diagram illustrating a clock generation circuit of a serializer including 5 phases according to an embodiment of the present invention. FIG. 4A is a circuit diagram illustrating a logic circuit unit of a serializer including 5 phases according to an embodiment of the present invention. FIG. 4B is a circuit diagram illustrating a drive circuit unit of a serializer including 5 phases according to an embodiment of the present invention. FIG. 4C is a timing diagram illustrating a serializer including 5 phases according to an embodiment of the present invention.

A representative example of the serializer shown in FIGS. 2A to 2C is a serializer that uses 5-phase signals as an input. A clock generation circuit, a logic circuit unit, and a drive circuit unit of the serializer using such 5 phases are shown in FIG. 3A, FIG. 4A, and FIG. 4B, respectively.

The clock generation circuit shown in FIG. 3A is used as a logic circuit that is capable of generating the first clock signal (φ_{—}<4:0>) and the second clock signal (φd_{—}<4:0>) for the serializer that uses 5-phase signals of the reference clock signal (φ<4:0>) as an input.

In order to generate the first and second clock signals, the clock signal circuit includes a combination circuit of multiple AND gates and multiple NAND gates. In more detail, in order to generate not only the first individual clock signal (i.e., the (1-0)-th individual clock signal (φ_<0>, the (1-1)-th individual clock signal (φ_<1>), etc.) but also the second individual clock signal (i.e., the (2-0)-th individual clock signal (φ_<0>, the (2-1)-th individual clock signal (φ_<1>), etc.), the clock signal circuit may include a combination of one AND gate and two NAND gates.

A circuit for generating each individual clock signal will hereinafter be described in detail.

In order to generate the (1-0)-th individual clock signal (φ_<0>), the 0-th individual reference clock (φ<0>) and the third individual reference clock (φ<3>) are connected to an input terminal of the 0-th NAND gate (ND0), and the first individual reference clock (φ<1>) and the fourth individual reference clock (φ<4>) are connected to the input terminal of the first NAND gate (ND1). The output signals of the 0-th NAND gate and the first NAND gate are connected to an input terminal of the fifth NAND gate (ND5), and the output signal of the fifth NAND gate is generated as the (1-0)-th individual clock signal.

In order to generate the (1-1)-th individual clock signal (φ_<1>), the first individual reference clock (φ<1>) and the fourth individual reference clock (φ<4>) are connected to an input terminal of the first NAND gate (ND1), the second individual reference clock (φ<2>) and the 0-th individual reference clock (φ<0>) are connected to an input terminal of the second NAND gate (ND1), the output signals of the first and second NAND gates are connected to an input terminal of the sixth NAND gate (ND6), and the output signal of the sixth NAND gate is generated as the (1-1)-th individual clock signal (φ_<1>).

The method for generating the (1-2)-th individual clock signal (φ_<2>), the (1-3)-th individual clock signal (φ_<3>), and the (1-4)-th individual clock signal (φ_<4>) is also similar to the above-mentioned method, and a detailed description thereof is shown in FIG. 3A.

In addition, in order to generate the (2-0)-th individual clock signal (φd_<0>), the third individual reference clock (φ<3>) and the fourth individual reference clock (φ<4>) are respectively connected to an inverting terminal and a non-inverting terminal of the third AND gate A3, and the output signal of the third AND gate is generated as the (2-0)-th individual clock signal (φd_<0>).

Likewise, in order to generate the (2-1)-th individual clock signal (φd_<1>), the fourth individual reference clock (φ<4>) and the 0-th individual reference clock (φ<0>) are respectively connected to an inverting terminal and a non-inverting terminal of the fourth AND gate A4, and the output signal of the fourth AND gate is generated as the (2-1)-th individual clock signal (φd_<1>). Clock signals of the (2-2)-th individual clock signal (φd_<2>) to the (2-4)-th individual clock signal (φd_<4>) are generated in the same manner as in the above-mentioned method, and a detailed description thereof is shown in FIG. 3A.

In response to an input of 5 reference clock signals (φ<4:0>), a timing diagram of 5 first clock signals (φ_{—}<4:0>) and 5 second clock signals (φd_{—}<4:0>) that are output from the logic circuit of the clock generation circuit shown in FIG. 3A is shown in FIG. 3B.

The logic circuit unit and the drive circuit unit of the serializer that uses 5-phase signals as an input are shown in FIG. 4A and FIG. 4B, respectively. The output signal (φo_{—}<4:0>) and the serialized data output signal (SER_OUT) of the serializer having 5-phase input signals are shown in FIG. 4C.

As shown in FIG. 4A, the logic circuit unit of the serializer that uses the 5-phase signals as an input includes 5 circuits, each of which includes one NOR gate and one D flip-flop interconnected in series for each data processing. In each circuit, the NOR gate receives the K-th data (DATA<K>) and the second clock signal (φd_<K>), and an output signal of the NOR gate is input to the D flip-flop. The D flip-flop processes data received from the NOR gate using the first clock signal (φ_<K>) applied to a clock terminal, and outputs the processed data to a gate terminal of the NMOS transistor corresponding to the drive circuit unit 230.

Referring to FIG. 4B, the drive circuit unit of the serializer that uses 5 phase signals as input signals includes a load resistor (RLOAD) between the power-supply voltage (VDD) and the output terminal (SER_OUT), and includes 5 NMOS transistors between the output terminal (SER_OUT) and the ground terminal.

As described above, the output signals (e.g., φo_<0>, φo_<1>, etc. of FIG. 4C) of the logic circuit unit, i.e., the output signals of the individual D flip-flops, are respectively applied to gate terminals (i.e., M₁, M₂, etc.) of the corresponding NMOS transistors from among the 5 NMOS transistors.

Each output signal of the logic circuit unit through each NMOS transistor is input in units of a time unit (i.e., t(0), t(1), t(2) or the like), and the data values (i.e., D0, D1, etc.) of the output signals (i.e., φo_<0>, φo_<1>, etc.) are serialized through the output terminal (SER_OUT) as shown in FIG. 4C, such that the serialized output signals are sequentially output.

As is apparent from the above description, the serializer according to the present invention can prevent the occurrence of glitch caused by a phase difference under phase alignment between data and a clock or between one clock and another clock. In more detail, differently from the conventional method, a D flip-flop is mounted to a logic circuit of the serializer according to the embodiment of the present invention, such that the inventive serializer can perform data serialization using the rising edge time of a clock signal, resulting in no glitch problems.

In addition, impedance from an output node to a ground terminal according to the present invention is lower than that of the conventional structure, such that the serializer according to the present invention is beneficial to a high-speed operation. In addition, the load resistance (RLOAD) is tuned in response to an operation frequency, such that the serializer according to the present invention can be applied to a broadband serializer.

While the present invention has been described with respect to the specific embodiments, it will be apparent to those skilled in the art that various changes and modifications may be made without departing from the spirit and scope of the invention as defined in the following claims.

What is claimed is:

1. A serializer comprising:
a clock generator configured to receive N reference clock signals (φ_<N−1:0>) (where N is a natural number) having different phases, and generate first clock signals (φ_<N−1:0>) and second clock signals (φd_<N−1:0>);
a logic circuit configured to generate output signals (φo_<N−1:0>) for N parallel data pieces using the first clock signals and the second clock signals; and
a drive circuit configured to serialize data corresponding to N output signals received from the logic circuit, and output the serialized data.

2. The serializer according to claim 1, wherein:
a K-th clock signal of the first clock signals (where K is a natural number) has two rising edge times, wherein a first rising edge time and a second rising edge time are located at times t(K) and t(K+1), respectively; and
a K-th clock signal of the second clock signals has one rising edge time, wherein the rising edge occurs at a time of generating a first falling edge of a K-th clock signal of the first clock signals, and a falling edge of the K-th clock signal of the second clock signals occurs at a time of generating a second falling edge of the K-th clock signal of the first clock signals.

3. The serializer according to claim 1, wherein the clock generator is configured as a combination of several AND gates and several NAND gates so as to generate the first clock signals and the second clock signals, and
wherein a combination of two NAND gates receiving different signals respectively is used to generate each of the first clock signals, and one AND gate receiving different signals respectively is used to generate each of the second clock signals.

4. The serializer according to claim 1, wherein the logic circuit includes a NOR gate and a D flip-flop which are used to process each of the N parallel data pieces and thus output an output signal corresponding to the processed data.

5. The serializer according to claim 4, wherein the drive circuit includes a load resistor between a power-supply voltage and an output terminal, and N branches including NMOS transistors configured to receive N signals from the logic circuit are located between the output terminal and a ground terminal of the drive circuit unit, such that the drive circuit serializes and outputs data corresponding to the output signal entered through each of the branch.
